(19) United States
(12) Patent Application Publication
(10) Pub. No.: US 2026/0341382 A1
(43) Pub. Date: Oct. 29, 2026

(54) READ ERROR HANDLING USING MEMORY CHARACTERISTICS

(71) Applicant: Micron Technology, Inc., Boise, ID (US)

(72) Inventors: Zixiang Loh, San Jose, CA (US); Patrick R. Khayat, San Diego, CA (US); Steven Michael Kientz, Westminster, CO (US); Shantilal Doru, San Diego, CA (US); Jun Wan, San Jose, CA (US)

(21) Appl. No.: 19/191,683

(22) Filed: Apr. 28, 2025

(51) Int. Cl. G11C 16/34; G11C 16/26

(52) U.S. Cl. CPC G11C 16/349; G11C 16/26; G11C 16/3418; G11C 2207/2254

(57) ABSTRACT

A system receives a request to read data from a portion of a memory device and determines if the request triggers a read error handling (REH) operation. If it does, the system selects an appropriate REH sequence based on characteristics of the memory device, which includes a different ordering of different types of REH operations. The system then performs the selected REH sequence to recover the data.

### TECHNICAL FIELD

Examples of the disclosure relate generally to memory sub-systems and, more specifically, to performing read error handling (REH) operations.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 illustrates a flow diagram of operations performed using the REH component, in accordance with some examples.

FIG. 3 illustrates a flow diagram of operations performed using the REH component, in accordance with some examples.

FIG. 4 illustrates a flow diagram of operations performed using the REH component, in accordance with some examples.

FIG. 5 illustrates a flow diagram of operations performed using the REH component, in accordance with some examples.

FIG. 6 illustrates a flow diagram of a REH sequence performed using the REH component, in accordance with some examples.

FIG. 7 illustrates a flow diagram of a REH sequence performed using the REH component, in accordance with some examples.

FIG. 8 is a block diagram of an example computer system, according to some examples.

### DETAILED DESCRIPTION

The present disclosure is directed to a system including a memory device and a processing device, operatively coupled to the memory device, configured to perform operations that improve read error handling (REH). Specifically, the disclosed processing device selects, from a plurality of REH sequences, an individual REH sequence based on one or more characteristics of the memory device. The characteristics include program-erase cycle (PEC) count and charge loss estimation associated with the memory device. The processing device implements a decision-tree approach to adaptively reorder REH steps based on these characteristics, selecting either a two-bit corrective read (2bCR) operation first or an auto-read calibration (ARC) operation first depending on the specific conditions. For example, when the PEC count is below a threshold (e.g., 5K), the processing device selects a sequence that prioritizes 2bCR operations. When the PEC count exceeds the threshold, the processing device evaluates the charge loss estimation (e.g., using bin-N of the BFEA table) to determine whether to prioritize 2bCR or ARC operations. This adaptive approach minimizes REH latency, resulting in improved system performance, reduced power consumption, and decreased read-disturb impact compared to conventional static REH sequences. The processing device continuously monitors the memory device conditions and adjusts the REH sequence accordingly, providing an intelligent solution that responds to NAND wear and retention conditions throughout the device lifecycle.

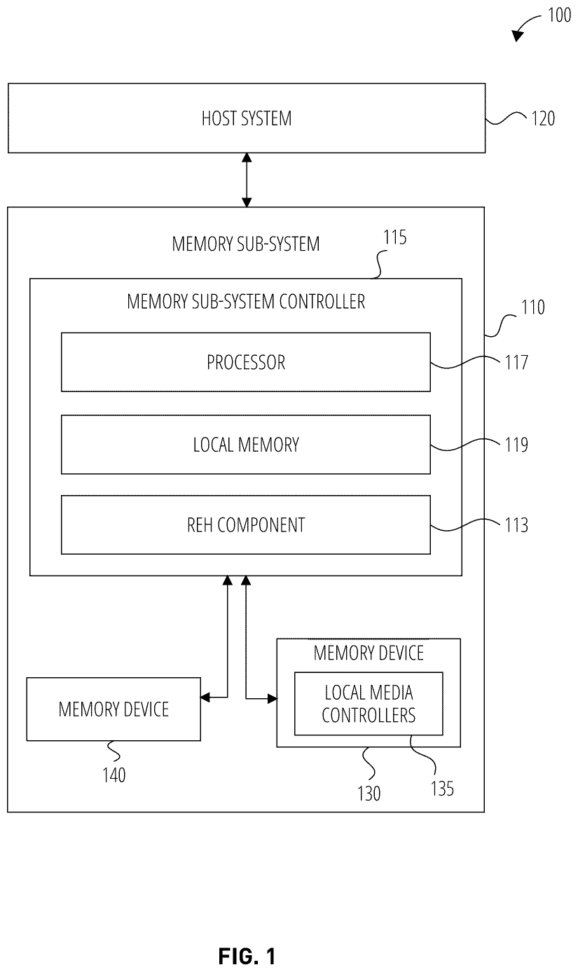

A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can send access requests to the memory sub-system, such as to store data at the memory sub-system and to read data from the memory sub-system.

The host system can send access requests (e.g., write command, read command, erase command) to the memory sub-system, such as to store data on a memory device at the memory sub-system, read data from the memory device on the memory sub-system, or write/read constructs (e.g., such as submission and completion queues) with respect to a memory device on the memory sub-system. The data to be read or written, as specified by a host request, is hereinafter referred to as “host data” or “user data.”

A host request can include logical address information (e.g., logical block address (LBA), namespace) for the host data, which is the location the host system associates with the host data and a particular zone in which to store or access the host data. The logical address information (e.g., LBA, namespace) can be part of metadata for the host data. Metadata can also include error handling data (e.g., error-correcting code (ECC) code word, parity code), data version (e.g., used to distinguish age of data written), valid bitmap (which LBAs or logical transfer units contain valid data), and so forth.

The memory sub-system can initiate media management operations, such as a write operation, on host data that is stored on a memory device. For example, firmware of the memory sub-system may rewrite previously written host data from a location of a memory device to a new location as part of garbage collection (GC) management operations. The data that is rewritten, for example as initiated by the firmware, is hereinafter referred to as “GC data.” Examples of system data include, but are not limited to, system tables (e.g., logical-to-physical memory address mapping table, also referred to herein as a logical-to-physical (L2P) mapping table (referred to as an L2P table), data from logging, scratch pad data, and so forth).

A memory device can be a non-volatile memory device. A non-volatile memory device is a package of one or more die. Each die can be comprised of one or more planes. For some types of non-volatile memory devices (e.g., AND-type devices), each plane is comprised of a set of physical blocks. For some memory devices, blocks are the smallest area that can be erased. Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which are a raw memory device combined with a local embedded controller for memory management within the same memory device package. The memory device can be divided into one or more zones where each zone is associated with a different set of host data or user data or application.

Certain memory devices, such as NAND-type memory devices, comprise one or more blocks, (e.g., multiple blocks), with each of those blocks comprising multiple memory cells. For instance, a memory device can comprise multiple pages (also referred to as word lines (WLs)), with each page comprising a subset of memory cells of the memory device. A threshold voltage (VT) of a memory cell (of a block) can be the voltage at which the floating gate (e.g., NAND transistor), implementing the memory cell, turns on and conducts (e.g., to a bit line coupled to the memory cell). Generally, writing data to such memory devices involves programming (by way of a program operation) the memory devices at the page level of a block, and erasing data from such memory devices involves erasing the memory devices at the block level (e.g., page level erasure of data is not possible).

Conventional approaches to REH in non-volatile memory systems employ static sequences of error correction operations that proceed in a fixed, predetermined order. When a host read fails, these systems run through a set of steps sequentially, continuing with subsequent steps until decoding succeeds or all steps are exhausted. This static approach does not take into account the varying conditions of the NAND memory, such as wear levels or charge loss characteristics, which can significantly impact the effectiveness of different error correction techniques. The existing REH deployed in systems today progresses from step-1 to step-N in a rigid sequence whenever the previous step fails during the read and decoding stages, terminating only when decoding succeeds.

These conventional static REH sequences are inherently inefficient and wasteful of system resources. The average latency of such sequences is suboptimal, with the cumulative latency for the sequence often being the worst among different possible sequences. This inefficiency translates directly into increased power consumption and longer processing times, as the system may need to execute multiple error correction operations in a predetermined order regardless of their likelihood of success under specific memory conditions. The result is a non-intelligent REH sequence that does not respond to the NAND condition, leading to suboptimal performance in terms of both speed and power consumption across the device lifecycle.

The present disclosure addresses these inefficiencies by implementing an adaptive REH approach that intelligently selects and reorders error correction operations based on memory device characteristics. Specifically, the system utilizes PEC counts and charge loss estimations (e.g., slow charge loss (SCL)) to construct a decision tree that determines an efficient REH sequence for specific memory conditions. Rather than applying a static, one-size-fits-all approach, the disclosed system evaluates whether to prioritize one type of REH operation (e.g., two-bit corrective read (2bCR) operations) or another type of REH operation (e.g., auto-read calibration (ARC) operations) based on the current state of the memory device or portion of the memory device being read. This adaptive methodology can reduce REH latency, resulting in improved system performance, reduced power consumption, and decreased read-disturb impact compared to conventional static approaches. The system can continuously monitor memory conditions and adjust the REH sequence accordingly, providing an intelligent solution that responds dynamically to NAND wear and retention conditions throughout the device lifecycle.

In some examples, a system for adaptive REH is provided that includes a memory device and a processing device coupled to the memory device. The processing device receives requests to read data from portions of the memory device and determines when these requests trigger REH operations. When an REH operation is needed, the processing device selects an appropriate REH sequence from multiple available sequences based on specific characteristics of the memory portion being accessed. Each REH sequence includes a different ordering of various types of error correction operations, allowing for optimized error recovery based on current memory conditions.

The processing device evaluates key memory characteristics including PEC count and charge loss estimation to make intelligent decisions about which REH sequence to implement. By determining these characteristics for the specific portion of memory being accessed, the processing device can tailor its error handling approach to the actual condition of the memory cells. This adaptive approach represents a significant improvement over conventional static REH sequences that follow the same steps regardless of memory conditions.

When implementing this adaptive approach, the processing device may compare the PEC count to a threshold value to guide its decision-making process. For memory portions with PEC counts below the threshold, the processing device may select a sequence that prioritizes certain types of REH operations. Specifically, the processing device might perform a two-bit corrective read operation before an auto-calibration operation when the memory shows lower wear levels. This ordering takes advantage of the specific error characteristics typically found in less-worn memory cells. The two-bit corrective read operation provides increased read window margins through level-by-level sensing that corrects for cell-to-cell coupling and lateral charge migration. Meanwhile, the auto-read calibration operation allows for on-die calibration of read levels before strobing at the calibrated position. By intelligently ordering these operations based on memory conditions, the processing device can achieve faster error recovery with lower latency.

For memory portions with higher PEC counts exceeding the threshold, the processing device performs additional analysis by comparing the charge loss estimation to another threshold value. Based on this comparison, the processing device selects either the first REH sequence or an alternative REH sequence better suited to highly worn memory cells. This multi-level decision process ensures optimal error handling across the entire lifecycle of the memory device. The processing device may determine charge loss estimation through various means, including accessing bin values from a block family error avoidance (BFEA) table associated with the memory portion. These bin values correspond to charge loss estimations and provide valuable information about the retention characteristics of the memory cells. By incorporating this information into the REH sequence selection process, the processing device can better address the specific error patterns likely to occur in the memory portion.

Depending on the memory characteristics, the processing device may determine that a specific REH sequence should include both two-bit corrective read operations and auto-read calibration operations, but in a particular order. For some memory conditions, performing the two-bit corrective read operation before the auto-read calibration operation yields better results, while for other conditions, the reverse order is more effective. This flexibility allows the processing device to optimize error recovery based on the specific error patterns present in the memory. The system may also incorporate SCL estimation as part of its decision-making process. SCL provides information about data retention capabilities of the memory cells over time, allowing the processing device to select REH sequences that address the specific types of errors that occur as charge gradually leaks from the floating gates of NAND cells.

Latency considerations play an important role in the selection of REH sequences. The processing device may determine the latency associated with each available REH sequence and select the one that minimizes overall processing time while still effectively recovering the data. This approach improves memory sub-system performance by reducing the time spent on error handling operations. Read-disturb impact is another factor that may influence REH sequence selection. Read disturb occurs when repeated read operations cause unintended changes in the threshold voltages of adjacent cells. By selecting REH sequences that minimize read-disturb impact, the processing device can preserve data integrity in neighboring cells while still effectively recovering data from the current read operation.

The processing device implements a progressive approach to REH, where it may determine that a first type of REH operation has failed and then proceed to perform a second type of REH operation in response. This ensures that simpler, faster operations are attempted first, with more complex operations only performed when necessary, optimizing both performance and power consumption. To facilitate efficient decision-making, the processing device may construct a decision tree based on PEC counts and charge loss estimations. By traversing this decision tree based on the characteristics of the memory portion, the processing device can quickly select the most appropriate REH sequence without having to evaluate all possible options for every read operation.

The adaptive REH approach can be applied to various portions of the memory device, including memory blocks, block stripes, or memory dies. This flexibility allows the processing device to tailor its REH approach to different levels of memory organization, from individual blocks to entire dies, depending on where errors are detected.

The system can be particularly well-suited for implementation with three-dimensional (3D) NAND devices, which present unique challenges for error handling due to their complex cell structure and inter-layer interactions. By adapting REH sequences to the specific characteristics of 3D NAND memory, the processing device can provide more effective error recovery than conventional approaches.

The adaptive REH methodology can be implemented not only in dedicated hardware systems but also through software instructions stored on non-transitory machine-readable storage media. When executed by a processing device, these instructions cause the device to perform the adaptive REH operations, allowing for flexible deployment across various system architectures. The overall method comprises receiving read requests, determining when REH operations are needed, selecting appropriate REH sequences based on memory characteristics, and performing those sequences to recover data. This methodical approach ensures consistent, optimized error handling across the memory system, improving both performance and reliability throughout the device lifecycle.

Though various examples are described herein as being implemented with respect to a memory sub-system (e.g., a controller of the memory sub-system), some or all of the portions of an example can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, memory device 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND type flash memory and write-in-place memory, such as a three-dimensional (3D) cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells, such as multi-level cells (MLCs), tri-level cells (TLCs), quad-level cells (QLCs), and penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or BSs. As used herein, a block including SLCs can be referred to as a SLC block, a block including MLCs can be referred to as a MLC block, a block including TLCs can be referred to as a TLC block, and a block including QLCs can be referred to as a QLC block.

Although non-volatile memory components such as NAND type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing GC operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., LBA, namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controllers 135) for media management within the same memory device package. An example of a managed memory device is a managed NAND (MNAND) device. Any operation discussed as being performed by the memory sub-system controller 115 can be similarly performed by the local media controllers 135 and vice versa.

The memory sub-system controller 115 includes a REH component 113 that is a specialized module within the memory sub-system controller 115 that implements adaptive REH techniques to improve memory operations. The REH component 113 may be configured to receive requests to read data from portions of memory devices connected to the memory sub-system 110. When a read request is received, the REH component 113 determines whether the request triggers a REH operation, which may occur when errors are detected during the initial read attempt.

Upon determining that REH is needed, the REH component 113 evaluates certain characteristics of the memory device 130 or the specific portion being accessed. These characteristics may include PEC counts, which indicate the wear level of the memory cells, and charge loss estimations that reflect data retention capabilities. In addition to PEC counts and charge loss estimations, the REH component 113 may also consider temperature characteristics of the memory device, which can significantly impact error patterns and read reliability. The REH component 113 may evaluate temperature data from internal sensors and adjust REH sequences accordingly, including potentially freezing temperature coefficients during calibration operations to improve read accuracy.

The REH component 113 may also assess the potential read-disturb impact of different error correction sequences, as read disturb occurs when repeated read operations cause unintended changes in threshold voltages of adjacent cells on unselected word lines within the same block, potentially leading to data corruption in neighboring cells if left unmanaged. Additionally, the REH component 113 may analyze the expected latency of different error correction sequences based on the specific memory conditions, allowing the REH component 113 to select sequences that reduce processing time while still effectively recovering data, improving overall system performance. Furthermore, the REH component 113 may examine bin values from BFEA tables associated with the memory portion, which provide detailed information about error characteristics beyond simple charge loss estimations, allowing for more nuanced selection of REH sequences based on the specific error patterns likely to occur in that memory portion.

The REH component 113 can maintain access to multiple REH sequences, each including different orderings of REH operations. These REH sequences may include different types of REH operations such as two-bit corrective read (2bCR), auto-read calibration (ARC), and other specialized error correction techniques. Using a decision tree approach (or other suitable modeling technique), the REH component 113 selects the most appropriate error handling sequence based on the memory characteristics. For example, when the memory device 130 or portion being read is associated with a first set of characteristics (e.g., a PEC count is below a threshold value (such as 5K cycles)), the REH component may select an REH sequence that prioritizes one type of REH operations, such as 2bCR operations, before another type of REH operations, such as ARC operations.

Conversely, when the memory device 130 or portion being read is associated with a second set of characteristics, such as the PEC count exceeds the threshold, the REH component 113 may evaluate additional factors such as the bin value from a BFEA table, which corresponds to charge loss estimation (e.g., SCL). If this bin value is below a certain threshold (such as 14), the REH component 113 may still prioritize 2bCR operations; otherwise, it may select a sequence that performs ARC operations first.

The REH component 113 can access information about the memory device 130 through various means, including bin values from BFEA tables and SCL estimations. These data points allow the REH component 113 to make informed decisions about which REH sequence would be most effective for the current memory conditions or characteristics. When implementing the selected REH sequence, the REH component 113 may perform operations in a specific REH order determined to be suitable for the current memory state. This may involve reordering REH steps that were traditionally performed in a fixed sequence in conventional systems.

The REH component 113 may also consider factors such as latency, power consumption, and read-disturb impact when selecting and implementing error handling sequences. By minimizing these factors, the REH component 113 can improve overall system performance and efficiency. Throughout the REH process, the REH component 113 may monitor the success of each operation and proceed to subsequent operations if earlier ones fail. This progressive approach ensures that simpler, faster operations are attempted before more complex, time-consuming ones.

The REH component 113 can be implemented in various parts of a computing system, including within the memory sub-system controller 115, in the host system 120, or distributed across multiple components. This flexibility allows for integration with different system architectures.

The adaptive nature of the REH component 113 allows it to respond dynamically to changing memory conditions throughout the device lifecycle. As memory cells wear and their characteristics change, the REH component 113 can adjust its error handling strategies accordingly.

By continuously evaluating memory characteristics and selecting appropriate REH sequences, the REH component 113 can maintain optimal performance even as memory devices age and experience wear. This adaptive approach represents an improvement over conventional static error handling methods.

Any discussion with respect to the memory device 130 can similarly be applied to the memory device 140.

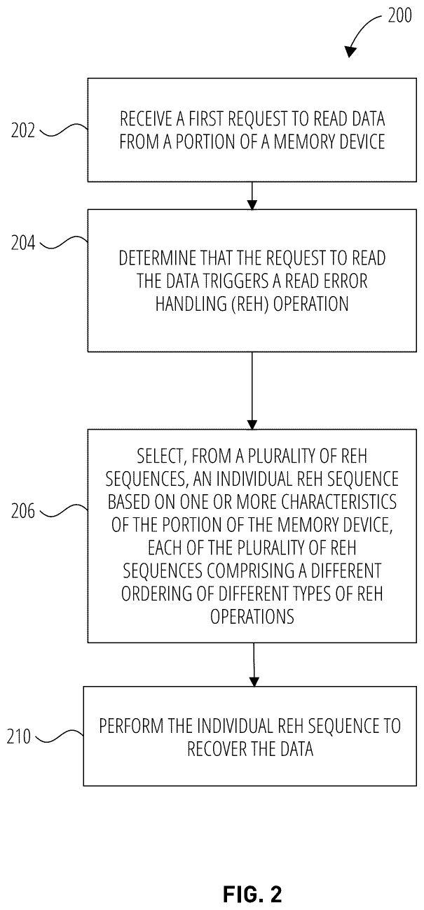

FIG. 2 is a flow diagram 200 of an example routine (method or process) performed using the REH component 113, in accordance with some examples. The method or process of diagram 200 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 200 is performed by the memory sub-system controller 115 or subcomponents of the memory sub-system controller 115 of FIG. 1. In these examples, the method or process of diagram 200 can be performed, at least in part, by the REH component 113. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

Referring now to FIG. 2, the method or process of diagram 200 begins at operation 202, with the REH component 113 of a memory sub-system 110 (e.g., memory device 140) receiving a first request to read data from a portion of a memory device. This operation represents the initial step where the memory sub-system 110 receives a read request from a host system 120 or another component within the memory sub-system 110.

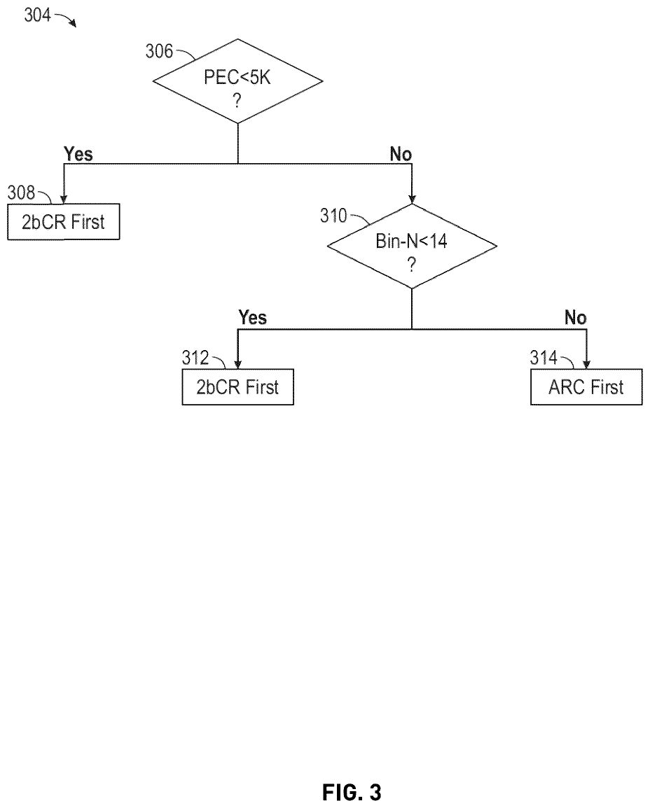

At operation 204, the REH component 113 determines that the request to read the data triggers a REH operation. This determination may be based on detecting errors during the initial read attempt, such as when the read bit error rate (RBER) exceeds a threshold value, indicating that standard error correction techniques are insufficient to recover the data reliably. At operation 206, the REH component 113 selects, from a plurality of REH sequences, an individual REH sequence based on one or more characteristics of the portion of the memory device. Each of the plurality of REH sequences can include a different ordering of different types of REH operations. The characteristics considered may include PEC count, charge loss estimation, temperature characteristics, and/or bin values from BFEA tables, and so forth. This selection process involves evaluating which sequence would be most effective for the current memory conditions, potentially using a decision tree approach, as shown in FIG. 3.

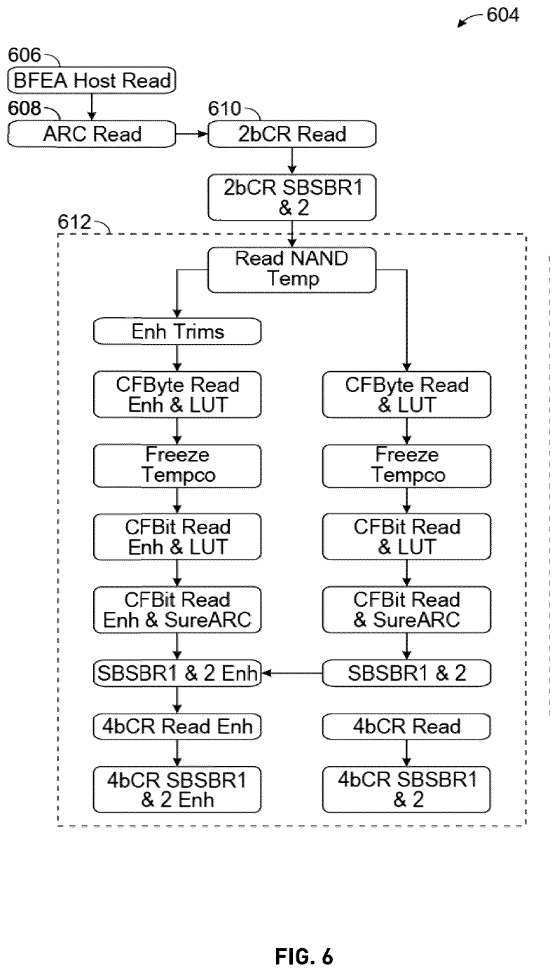

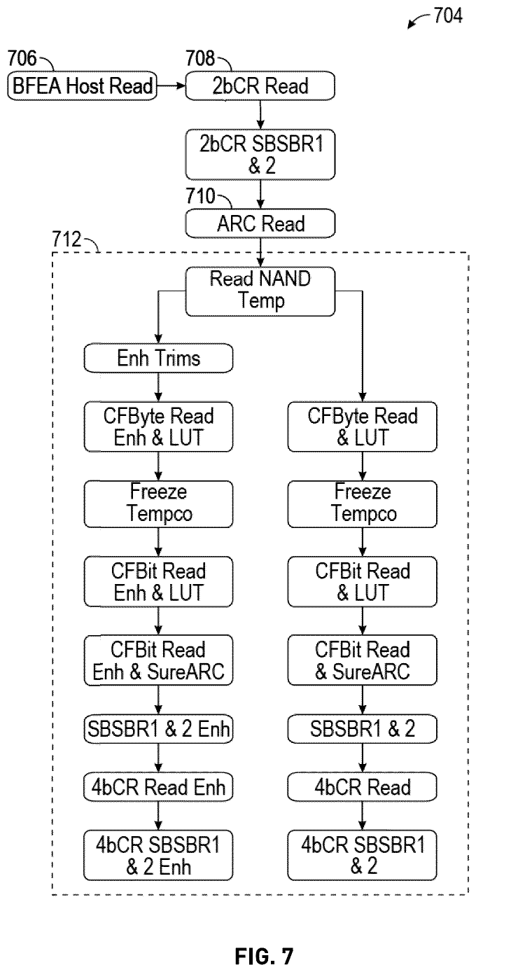

Finally, at operation 210, the REH component 113 performs the individual REH sequence to recover the data. This involves executing the selected sequence of error correction operations in the specific order determined to be optimal for the current memory state. The sequence may include operations such as two-bit corrective read (2bCR), auto-read calibration (ARC), and other specialized error correction techniques, as illustrated in FIG. 6 and FIG. 7.

FIG. 3 illustrates a flow diagram of a decision tree 304 used by the REH component 113, in accordance with some examples. Specifically, FIG. 3 illustrates a flow diagram of a decision tree 304 used by the REH component 113 to adaptively select an appropriate REH sequence based on memory device characteristics. The decision tree 304 represents a structured approach to determining which REH sequence will be most effective for specific memory conditions, allowing for optimized error recovery with minimal latency.

At operation 306, the REH component 113 evaluates whether the PEC count of the memory portion is less than a threshold value of, for example 5K (5,000 cycles). This initial decision point serves as the primary branch in the tree, dividing memory portions into those with relatively low wear (below 5K cycles) and those with higher wear levels (5K cycles or more). If the result of operation 306 is “Yes” (PEC<5K), the decision tree 304 follows the left branch to operation 308, which indicates that a first type of REH operation (part of a first REH sequence), such as “2bCR” REH sequence, should be selected. This sequence can prioritize two-bit corrective read operations (e.g., a first type of REH operation) before auto-read calibration operations (e.g., a second type of REH operation), as shown in detail in FIG. 7. This approach is generally more effective for memory with lower wear levels.

If the result of operation 306 is “No” (PEC≥5K), the decision tree 304 follows the right branch to operation 310, which represents a secondary evaluation of the memory characteristics. Specifically, at operation 310 the REH component 113 evaluates whether the bin value (Bin-N) from the BFEA table of the portion being read is less than a specified value, such as 14. The bin value assessed in operation 310 corresponds to a charge loss estimation for the memory portion, with higher bin values indicating greater charge loss. This secondary evaluation allows the REH component 113 to further refine its REH sequence selection based on the retention characteristics of the memory cells, even among those with higher wear levels.

If the result of operation 310 is “Yes” (Bin-N<14), the decision tree 304 follows the left branch to operation 312, which also indicates that a first REH sequence, such as “2bCR” should be selected. This demonstrates that even for memory with higher wear levels, the first REH sequence starting with two-bit corrective read approach may still be more effective if the charge loss is relatively low. If the result of operation 310 is “No” (Bin-N≥14), the decision tree 304 follows the right branch to operation 314, which indicates that another REH sequence where another type of REH operation is performed first, such as “ARC” should be selected. This sequence can prioritize auto-read calibration operations before two-bit corrective read operations, as shown in detail in FIG. 6. This approach is generally more effective for memory with both high wear levels and significant charge loss.

The decision tree structure illustrated in FIG. 3 enables the REH component 113 to make intelligent, adaptive decisions about error handling sequences based on readily available memory characteristics. By considering both PEC count and charge loss estimation (via BFEA bin values), the REH component 113 can select the most appropriate REH sequence for specific memory conditions, resulting in improved performance, reduced power consumption, and decreased read-disturb impact compared to conventional static approaches.

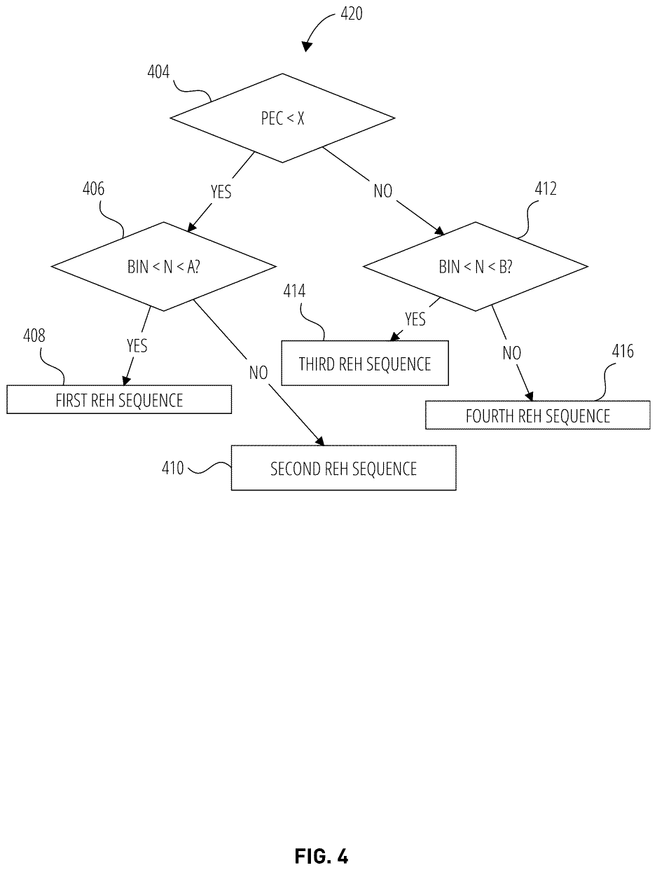

FIG. 4 illustrates a flow diagram of operations (e.g., routine 420) performed using the REH component 113, in accordance with some examples. Specifically, FIG. 4 illustrates a decision tree structure for selecting an appropriate REH sequence based on memory device 130 characteristics.

The process begins at operation 404 with a first decision node that evaluates whether the PEC count of a memory portion being read is less than a threshold value, such as X. This initial PEC evaluation helps the REH component 113 determine the wear level of the memory device 130. If the PEC count is less than the threshold value (YES path from operation 404), the flow proceeds to operation 406, where the REH component 113 evaluates whether a current bin value N assigned to the memory portion being read falls within a first range (BIN<N<A?). The current bin value represents charge loss estimation derived from the BFEA table.

From operation 406, if the bin value is within the specified range (YES path), the REH component 113 selects a first REH sequence at operation 408. This sequence can be optimized for low PEC count and moderate charge loss conditions. If the bin value is not within the specified range at operation 406 (NO path), the REH component 113 selects the second REH sequence at operation 410. The first REH sequence can be any of the REH sequences discussed herein different from the second REH sequence.

For example, as shown in FIG. 7, this first REH sequence can begin with a BFEA host read followed by performing the 2bCR operations first, then the ARC operations. This can be followed by additional error handling operations If the current bin value is not within range A (NO path from operation 406), the second REH sequence can be selected at operation 410. As shown in FIG. 6, this second sequence performs the ARC operations before the 2bCR operations, followed by additional error handling operations

Returning to the initial PEC evaluation at operation 404, if the PEC count is not less than the threshold value, X (NO path), the flow proceeds to operation 412, where the REH component 113 evaluates whether the current bin value N falls within a second range (BIN<N<B?). From operation 412, if the bin value is within the second specified range (YES path), the REH component 113 selects the third REH sequence at operation 414. If the current bin value is not within the second specified range at operation 412 (NO path), the REH component 113 selects the fourth REH sequence at operation 416.

Each REH sequence represents a different ordering of error handling operations, including two-bit corrective read (2bCR) operations followed by auto-read calibration (ARC) operations or vice versa and/or any other suitable sequence that combines different REH operations. The sequences are designed to minimize latency based on the specific memory conditions indicated by the PEC count and charge loss estimation. The first REH sequence can be the same or different from the third and fourth REH sequences. The second REH sequence can be the same or different from the third and fourth REH sequences. The third and fourth REH sequences are different from each other.

The decision tree structure enables adaptive selection of REH sequences that are optimized for different combinations of wear levels and charge loss conditions, improving overall system performance compared to static REH approaches.

The different sequences represent varying orderings of operations like 2bCR, ARC, and other error handling steps, with the ordering optimized for the specific memory conditions indicated by the decision tree path. This adaptive methodology provides an intelligent solution that responds dynamically to NAND wear and retention conditions throughout the device lifecycle, improving system performance while maintaining data reliability.

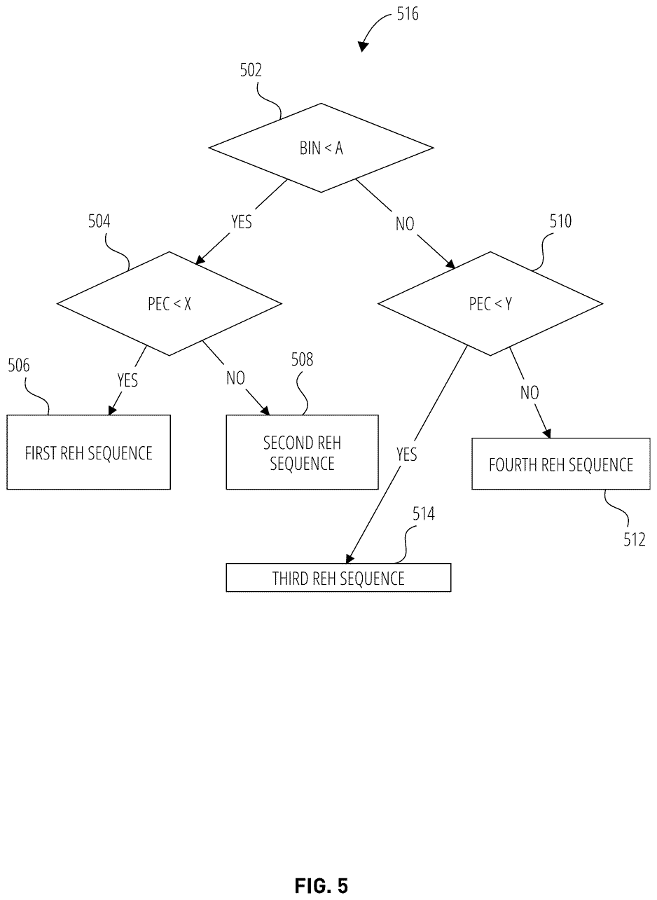

FIG. 5 illustrates a flow diagram of operations (e.g., routine 516) performed using the REH component 113, in accordance with some examples. Specifically, FIG. 5 illustrates an alternative decision tree structure for selecting an appropriate REH sequence based on memory device 130 characteristics.

The process begins at operation 502 with a first decision node that evaluates whether a current bin value is less than a threshold value A. The current bin value represents charge loss estimation derived from the BFEA table. If the current bin value is less than threshold A (YES path from operation 502), the REH component 113 proceeds to operation 504, which evaluates whether the PEC count is less than a threshold value, such as X. From operation 504, if the PEC count is less than the threshold value (YES path), the REH component 113 selects the first REH sequence at operation 506. If the PEC count is not less than X (NO path), the REH component 113 selects the second REH sequence at operation 508.

As shown in FIG. 7, the first REH sequence begins with a BFEA host read followed by performing the 2bCR operations first, then the ARC operations. Specifically, the sequence performs BFEA host read, 2bCR Read, 2bCR SBSBR1 & 2, ARC Read, followed by additional error handling operations. Returning to the initial bin value evaluation at operation 502, if the current bin value is not less than threshold A (NO path), the flow proceeds to operation 510, where the REH component 113 evaluates whether the PEC count is less than another threshold value, such as Y. From operation 510, if the PEC count is less than Y (YES path), the REH component 113 selects the third REH sequence at operation 514. If the PEC count is not less than Y (NO path), the REH component 113 selects the fourth REH sequence at operation 512.

Each REH sequence represents a different ordering of error handling operations, including two-bit corrective read (2bCR) operations followed by auto-read calibration (ARC) operations or vice versa. The sequences are designed to minimize latency based on the specific memory conditions indicated by the charge loss estimation and PEC count. The first REH sequence can be the same or different from the third and fourth REH sequences. The second REH sequence can be the same or different from the third and fourth REH sequences. The third and fourth REH sequences are different from each other.

The decision tree structure enables adaptive selection of REH sequences that are optimized for different combinations of charge loss conditions and wear levels, improving overall system performance compared to static REH approaches.

This adaptive methodology provides an intelligent solution that responds dynamically to NAND charge loss and wear conditions throughout the device lifecycle, improving system performance while maintaining data reliability.

FIG. 6 illustrates a REH sequence 604 performed using the REH component 113, in accordance with some examples. Specifically, this REH sequence 604 represents the “ARC First” approach that is selected when the memory device has higher PEC counts and significant charge loss, as determined by the decision tree 304 shown in FIG. 3.

The REH sequence 604 begins with operation 606, which represents a BFEA host system 120 read operation. This initial operation 606 serves as the entry point for the REH sequence 604 and involves reading data from the memory device 130 using standard parameters based on the BFEA table. Following the BFEA host read, the REH sequence 604 proceeds to operation 608, which represents an ARC (Auto-Read Calibration) read operation. This operation is prioritized in this REH sequence 604 over the 2bCR REH operation and is performed before the two-bit corrective read operations. The operation 608 involves on-die calibration of read levels before strobing at the calibrated position to return data, which can be particularly effective for memory with high wear levels and significant charge loss.

After the operation 608, the REH sequence 604 continues to operation 610, which represents a 2bCR (Two-Bit Corrective Read) operation. This operation creates more accurate distributions of cells within each level by correcting for cell-to-cell coupling and lateral charge migration. In this sequence, the 2bCR operation is performed after the ARC operation, reflecting the optimal ordering for memory with higher PEC counts and significant charge loss.

The REH sequence 604 then proceeds to the 2bCR SBSBR1 & 2 operation, which extends the two-bit corrective read with additional sensing parameters. SBSBR (Sense-Based Soft-Bit Read) operations provide additional information about the reliability of each bit, further enhancing error correction capabilities. The remaining operations, collectively labeled as additional REH operations 612, include a series of increasingly complex error correction techniques that are performed if the earlier operations fail to recover the data. The additional REH operations 612 can, in some optional cases, be performed in any other suitable order and are not limited to being performed in the order shown. These include a Read NAND Temp operation, which reads the temperature of the NAND device to inform subsequent calibration operations; Enhanced Trims operations, which adjust various parameters to optimize read performance; CFByte Read operations with LUT, which perform calibration at the byte level; Freeze Tempco operations, which freeze the temperature coefficient to prevent temperature fluctuations from affecting calibration accuracy; CFBit Read operations with LUT and SureARC, which perform more granular calibration at the bit level; SBSBR1 & 2 operations, which provide additional soft-bit information to improve error correction; 4bCR (Four-Bit Corrective Read) operations, which provide even more detailed correction than 2bCR but at the cost of significantly higher latency; and 4bCR SBSBR1 & 2 operations, which combine the four-bit corrective read with soft-bit information for maximum error correction capability.

The operations are arranged in a specific order, with simpler, faster operations performed first and more complex, time-consuming operations performed later if needed. This progressive approach optimizes performance by attempting less resource-intensive solutions before resorting to more powerful but slower techniques.

FIG. 7 illustrates a REH sequence 704 performed using the REH component 113, in accordance with some examples. Specifically, this REH sequence 704 represents the “2bCR First” approach that is selected when the memory device 130 has lower PEC counts or when the PEC count exceeds the threshold but the charge loss estimation is below a threshold value, as determined by the decision tree shown in FIG. 3.

The REH sequence 704 begins with operation 706, which represents a BFEA host read operation. This initial operation 706 serves as the entry point for the REH sequence 704 and involves reading data from the memory device 130 using standard parameters based on the BFEA table. Following the BFEA host read, the REH sequence 704 proceeds to operation 708, which represents a 2bCR (Two-Bit Corrective Read) operation. This operation is prioritized in this REH sequence 704 over the ARC REH operation and is performed before the auto-read calibration operations. The operation 708 creates more accurate distributions of cells within each level by correcting for cell-to-cell coupling and lateral charge migration, which can be particularly effective for memory with lower wear levels or moderate charge loss.

After the 2bCR operation, the REH sequence 704 continues to the 2bCR SBSBR1 & 2 operation, which extends the two-bit corrective read with additional sensing parameters. SBSBR (Sense-Based Soft-Bit Read) operations provide additional information about the reliability of each bit, further enhancing error correction capabilities.

The REH sequence 704 then proceeds to operation 710, which represents an ARC (Auto-Read Calibration) operation. This operation involves on-die calibration of read levels before strobing at the calibrated position to return data. In this sequence, the ARC operation is performed after the 2bCR operations, reflecting the optimal ordering for memory with lower PEC counts or moderate charge loss.

The remaining operations, collectively labeled as additional REH operations 712, include a series of increasingly complex error correction techniques that are performed if the earlier operations fail to recover the data. The additional REH operations 712 can, in some optional cases, be performed in any other suitable order and are not limited to being performed in the order shown. These include Read NAND Temp operation, which reads the temperature of the NAND device to inform subsequent calibration operations; Enhanced Trims operations, which adjust various parameters to optimize read performance; CFByte Read operations with LUT, which perform calibration at the byte level; Freeze Tempco operations, which freeze the temperature coefficient to prevent temperature fluctuations from affecting calibration accuracy; CFBit Read operations with LUT and SureARC, which perform more granular calibration at the bit level; SBSBR1 & 2 operations, which provide additional soft-bit information to improve error correction; 4bCR (Four-Bit Corrective Read) operations, which provide even more detailed correction than 2bCR but at the cost of significantly higher latency; and 4bCR SBSBR1 & 2 operations, which combine the four-bit corrective read with soft-bit information for maximum error correction capability.

The operations are arranged in a specific order, with simpler, faster operations performed first and more complex, time-consuming operations performed later if needed. This progressive approach optimizes performance by attempting less resource-intensive solutions before resorting to more powerful but slower techniques.

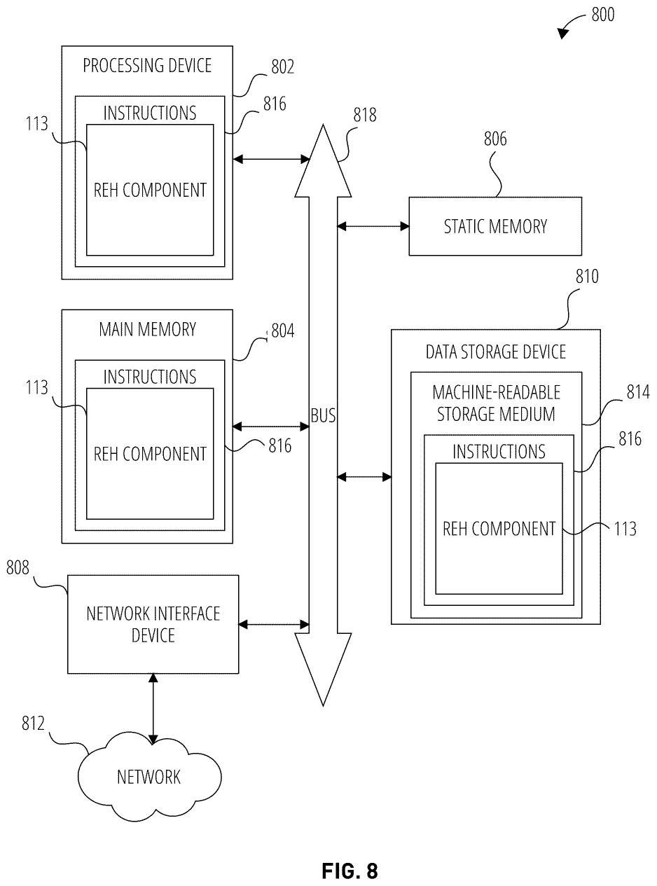

FIG. 8 illustrates an example machine in the form of a computer system 800 within which a set of instructions 816 can be executed for causing the machine to perform any one or more of the methodologies discussed herein. In some examples, the computer system 800 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., ROM, flash memory, DRAM such as SDRAM or Rambus DRAM (RDRAM), etc.), a static memory 806 (e.g., flash memory, static random access memory (SRAM), etc.), and a data storage device 810, which communicate with each other via a bus 818.

The processing device 802 represents one or more general-purpose processing devices such as a microprocessor, a central processing unit, or the like. More particularly, the processing device 802 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 802 can also be one or more special-purpose processing devices such as an application-specific integrated circuit (ASIC), a field programmable gate array (FPGA), a digital signal processor (DSP), a network processor, or the like. The processing device 802 is configured to execute instructions 816 for performing the operations and steps discussed herein. The computer system 800 can further include a network interface device 808 to communicate over a network 812.

The data storage device 810 can include a machine-readable storage medium 814 (also known as a computer-readable medium) on which is stored one or more sets of instructions 816 or software embodying any one or more of the methodologies or functions described herein. The instructions 816 can also reside, completely or at least partially, within the main memory 804 and/or within the processing device 802 during execution thereof by the computer system 800, the main memory 804 and the processing device 802 also constituting machine-readable storage media. The machine-readable storage medium 814, data storage device 810, and/or main memory 804 can correspond to the memory sub-system 110 of FIG. 1.

In one example, the instructions 816 include instructions to implement functionality corresponding to providing block failure protection for a zone memory sub-system as described herein (e.g., the REH component 113 of FIG. 1). While the machine-readable storage medium 814 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

Example 1. A system comprising: a memory device; and a processing device, coupled to the memory device, programmed to perform operations comprising: receiving a request to read data from a portion of the memory device; determining that the request to read the data triggers a read error handling (REH) operation; selecting, from a plurality of REH sequences, an individual REH sequence based on one or more characteristics of the portion of the memory device, each of the plurality of REH sequences comprising a different ordering of different types of REH operations; and performing the individual read error handling sequence to recover the data.

Example 2. The system of Example 1, the operations further comprising: determining a program-erase cycle (PEC) count associated with the portion of the memory device; and determining a charge loss estimation associated with the portion of the memory device, wherein the one or more characteristics comprise the PEC count and the charge loss estimation.

Example 3. The system of Example 2, the operations further comprising: comparing the PEC count to a threshold PEC value; and selecting a first REH sequence in response to determining that the PEC count is below the threshold PEC value, wherein the first REH sequence comprises performing a first type of REH operation before a second type of REH operation.

Example 4. The system of Example 3, wherein the first type of REH operation comprises a two-bit corrective read operation, and wherein the second type of REH operation comprises an auto-calibration operation.

Example 5. The system of any one of Examples 2-4, the operations further comprising: comparing the PEC count to a threshold PEC value; determining that the PEC count exceeds the threshold PEC value; and in response to determining that the PEC count exceeds the threshold PEC value, comparing the charge loss estimation to a threshold charge loss value.

Example 6. The system of Example 5, the operations further comprising: selecting a first REH sequence in response to determining that the charge loss estimation is below the threshold charge loss value.

Example 7. The system of Example 6, the operations further comprising: selecting a second REH sequence in response to determining that the charge loss estimation is below the threshold charge loss value.

Example 8. The system of any one of Examples 1-7, the operations further comprising: determining a bin value from a block family error avoidance (BFEA) table associated with the portion of the memory device, wherein the bin value corresponds to a charge loss estimation; and selecting the individual REH sequence based at least in part on the bin value.

Example 9. The system of any one of Examples 1-8, the operations further comprising: determining that the individual REH sequence includes a two-bit corrective read (2bCR) operation and an auto-read calibration (ARC) operation; and performing the 2bCR operation before the ARC operation based on the one or more characteristics of the portion of the memory device.

Example 10. The system of any one of Examples 1-9, the operations further comprising: determining that the individual REH sequence includes a two-bit corrective read (2bCR) operation and an auto-read calibration (ARC) operation; and performing the ARC operation before the 2bCR operation based on the one or more characteristics of the portion of the memory device.

Example 11. The system of any one of Examples 1-10, the operations further comprising: determining a slow charge loss (SCL) estimation for the portion of the memory device; and selecting the individual REH sequence based at least in part on the SCL estimation.

Example 12. The system of any one of Examples 1-11, the operations further comprising: determining a latency associated with each of the plurality of REH sequences; and selecting the individual REH sequence based at least in part on the latency.

Example 13. The system of any one of Examples 1-12, the operations further comprising: determining a read-disturb impact associated with each of the plurality of REH sequences; and selecting the individual REH sequence to minimize the read disturb impact.

Example 14. The system of any one of Examples 1-13, the operations further comprising: determining that a first type of REH operation in the individual REH sequence has failed; and performing a second type of REH operation in the individual REH sequence in response to failure of the first type of REH operation.

Example 15. The system of any one of Examples 1-14, the operations further comprising: constructing a decision tree based on program-erase cycle (PEC) counts and charge loss estimations; and selecting the individual REH sequence by traversing the decision tree based on the one or more characteristics of the portion of the memory device.

Example 16. The system of any one of Examples 1-15, wherein the one or more characteristics of the portion of the memory device comprise slow charge loss (SCL) and a program-erase cycle (PEC) count.

Example 17. The system of any one of Examples 1-16, wherein the portion of the memory device comprises a memory block, a block stripe, or a memory die.

Example 18. The system of any one of Examples 1-17, wherein the memory device comprises a three-dimensional (3D) NAND device.

Example 19. At least one non-transitory machine-readable storage medium comprising instructions that, when executed by a processing device, cause the processing device to perform operations comprising: receiving a first request to read data from a portion of a memory device; determining that the request to read the data triggers a read error handling (REH) operation; selecting, from a plurality of REH sequences, an individual REH sequence based on one or more characteristics of the portion of the memory device, each of the plurality of REH sequences comprising a different ordering of different types of REH operations; and performing the individual read error handling sequence to recover the data.

Example 20. A method comprising: receiving a first request to read data from a portion of a memory device; determining that the request to read the data triggers a read error handling (REH) operation; selecting, from a plurality of REH sequences, an individual REH sequence based on one or more characteristics of the portion of the memory device, each of the plurality of REH sequences comprising a different ordering of different types of REH operations; and performing the individual read error handling sequence to recover the data.

The term “coupled with” generally refers to a connection between components, which can be an indirect communicative connection or direct communicative connection (e.g., without intervening components), whether wired or wireless, including connections such as electrical, optical, magnetic, and the like.

“System data” hereinafter refers to data that is created and/or maintained by the memory sub-system for performing operations in response to host requests and for media management.

“User data” hereinafter generally refers to host data and garbage collection data.

“Read disturb” refers to a phenomenon where repeated read operations on a specific WL in a NAND flash memory block cause unintended changes in the threshold voltages of adjacent cells on unselected WLs within the same block. This effect can potentially lead to data corruption in neighboring cells if left unmanaged, necessitating periodic data refresh or block relocation (folding) operations to maintain data integrity in NAND-based storage devices.

“Folding” refers to an operation where data from multiple partially filled pages or blocks is combined and rewritten into a single page or block. This process helps to optimize storage space utilization, reduce write amplification, and improve overall performance of the NAND storage device by consolidating fragmented data and freeing up space for new writes. Folding and “relocation” operations are used interchangeably and mean the same thing.

“BFEA” refers to a sophisticated technique used to enhance the reliability and performance of NAND-based storage devices, particularly in solid-state drives (SSDs). BFEA (block family error avoidance) involves grouping or categorizing blocks with similar error characteristics to optimize error management strategies. In NAND flash memory, blocks can develop varying error rates over time due to factors such as wear, manufacturing variations, and environmental conditions. The block family error avoidance bin strategy addresses this by monitoring and analyzing the error rates of individual blocks, then grouping blocks with similar error profiles into “families” or “bins.” Once categorized, specific error management techniques are applied to each bin based on its unique error characteristics. This approach allows the memory controller to optimize error correction code (ECC) strategies, adjust read voltage thresholds more effectively, implement targeted wear-leveling algorithms, and prioritize blocks for garbage collection or retirement based on their error bin.

“Slow charge loss (SCL)” refers to charge retention loss or data retention loss that occurs in flash memory cells over time. SCL refers to the gradual leakage of electrical charge from the floating gate of a NAND cell, which can lead to data corruption or loss if left unchecked. This SCL is a natural aging process in flash memory and becomes more pronounced as the memory cells undergo more program/erase cycles and as the manufacturing process shrinks to smaller geometries. The rate of charge loss can be affected by factors such as temperature, the quality of the insulating oxide layer, and the overall design of the memory cell.

“PEC” refers to Program-Erase Cycles which is a measurement that indicates the amount of wear experienced by NAND flash memory, representing the number of times a NAND memory cell has been programmed and erased.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

What is claimed is:

1. A system comprising:
a memory device; and
a processing device, coupled to the memory device, programmed to perform operations comprising:
receiving a request to read data from a portion of the memory device;
determining that the request to read the data triggers a read error handling (REH) operation;
selecting, from a plurality of REH sequences, an individual REH sequence based on one or more characteristics of the portion of the memory device, each of the plurality of REH sequences comprising a different ordering of different types of REH operations; and
performing the individual REH sequence to recover the data.

2. The system of claim 1, the operations further comprising:
determining a program-erase cycle (PEC) count associated with the portion of the memory device; and
determining a charge loss estimation associated with the portion of the memory device, wherein the one or more characteristics comprise the PEC count and the charge loss estimation.

3. The system of claim 2, the operations further comprising:
comparing the PEC count to a threshold PEC value; and
selecting a first REH sequence in response to determining that the PEC count is below the threshold PEC value, wherein the first REH sequence comprises performing a first type of REH operation before a second type of REH operation.

4. The system of claim 3, wherein the first type of REH operation comprises a two-bit corrective read operation, and wherein the second type of REH operation comprises an auto-calibration operation.

5. The system of claim 2, the operations further comprising:
comparing the PEC count to a threshold PEC value;
determining that the PEC count exceeds the threshold PEC value; and
in response to determining that the PEC count exceeds the threshold PEC value, comparing the charge loss estimation to a threshold charge loss value.

6. The system of claim 5, the operations further comprising:
selecting a first REH sequence in response to determining that the charge loss estimation is below the threshold charge loss value.

7. The system of claim 6, the operations further comprising:
selecting a second REH sequence in response to determining that the charge loss estimation is below the threshold charge loss value.

8. The system of claim 1, the operations further comprising:
determining a bin value from a block family error avoidance (BFEA) table associated with the portion of the memory device, wherein the bin value corresponds to a charge loss estimation; and
selecting the individual REH sequence based at least in part on the bin value.

9. The system of claim 1, the operations further comprising:
determining that the individual REH sequence includes a two-bit corrective read (2bCR) operation and an auto-read calibration (ARC) operation; and
performing the 2bCR operation before the ARC operation based on the one or more characteristics of the portion of the memory device.

10. The system of claim 1, the operations further comprising:
determining that the individual REH sequence includes a two-bit corrective read (2bCR) operation and an auto-read calibration (ARC) operation; and
performing the ARC operation before the 2bCR operation based on the one or more characteristics of the portion of the memory device.

11. The system of claim 1, the operations further comprising:
determining a slow charge loss (SCL) estimation for the portion of the memory device; and
selecting the individual REH sequence based at least in part on the SCL estimation.

12. The system of claim 1, the operations further comprising:
determining a latency associated with each of the plurality of REH sequences; and
selecting the individual REH sequence based at least in part on the latency.

13. The system of claim 1, the operations further comprising:
determining a read disturb impact associated with each of the plurality of REH sequences; and
selecting the individual REH sequence to minimize the read-disturb impact.

14. The system of claim 1, the operations further comprising:
determining that a first type of REH operation in the individual REH sequence has failed; and
performing a second type of REH operation in the individual REH sequence in response to failure of the first type of REH operation.

15. The system of claim 1, the operations further comprising:
constructing a decision tree based on program-erase cycle (PEC) counts and charge loss estimations; and
selecting the individual REH sequence by traversing the decision tree based on the one or more characteristics of the portion of the memory device.

16. The system of claim 1, wherein the one or more characteristics of the portion of the memory device comprise slow charge loss (SCL) and a program-erase cycle (PEC) count.

17. The system of claim 1, wherein the portion of the memory device comprises a memory block, a block stripe, or a memory die.

18. The system of claim 1, wherein the memory device comprises a three-dimensional (3D) NAND device.

19. At least one non-transitory machine-readable storage medium comprising instructions that, when executed by a processing device, cause the processing device to perform operations comprising:
receiving a request to read data from a portion of a memory device;
determining that the request to read the data triggers a read error handling (REH) operation;
selecting, from a plurality of REH sequences, an individual REH sequence based on one or more characteristics of the portion of the memory device, each of the plurality of REH sequences comprising a different ordering of different types of REH operations; and
performing the individual REH sequence to recover the data.

20. A method comprising:
receiving a request to read data from a portion of a memory device;
determining that the request to read the data triggers a read error handling (REH) operation;
selecting, from a plurality of REH sequences, an individual REH sequence based on one or more characteristics of the portion of the memory device, each of the plurality of REH sequences comprising a different ordering of different types of REH operations; and
performing the individual REH sequence to recover the data.
